(19) United States
(12) Patent Application Publication
(10) Pub. No.: US 2009/0218692 A1
(43) Pub. Date: Sep. 3, 2009

(54) Barrier for Copper Integration in the FEOL

(76) Inventor: Roland Hampp, Poughkeepsie, NY (US)

Correspondence Address: SLATER & MATSIL LLP, 17950 PRESTON ROAD, SUITE 1000, DALLAS, TX, 75252, US

(21) Appl. No.: 12/040,441

(22) Filed: Feb. 29, 2008

(51) Int. Cl. H01L 21/768; H01L 23/52

(52) U.S. Cl. 257/751; 438/653; 257/E21.585; 257/E23.141

(57) ABSTRACT

Copper integration in the FEOL stage is disclosed for a preliminary semiconductor device by forming a recess in a substrate of the device, the recess having a bottom surface and sidewall surfaces, depositing a barrier layer having about a 100% step coverage on the sidewall surfaces and the bottom surface, and depositing copper into the recess over the barrier layer to form a contact providing electrical connection to the preliminary semiconductor device.

### TECHNICAL FIELD

The present invention relates, in general, to semiconductor fabrication, and, more particularly, to a barrier for copper integration in the front-end-of-line (FEOL) processing.

### BACKGROUND

Semiconductor devices continue to become smaller and smaller as technology advances to support such smaller-sized devices. In the FEOL processing stages, conductors, such as tungsten, have been used for contacts. However, the relationship between size and conducting contacts provides that the contact resistance is inversely proportional to the size of the contact area. Thus, as the sizes get smaller, the contact resistance increases. Because the conductivity of tungsten becomes less desirable at the smallest sizes currently being developed, i.e., 32 nm node sizes, a search for new conducting material has been undertaken.

Copper, which has a much greater conductivity than tungsten, has been studied for replacing these current FEOL materials. In current attempts to use copper in FEOL metallization processing, a contact resistance improvement has been seen of up to 65%, which greatly increases the performance of the copper-metallized FEOL layers. This contact resistance improvement corresponds to an actual device performance improvement of 5% in ‘N’-type field effect transistors (NFETs) and 6% in ‘P’-type FETs (PFETs) in study tests. However, along with the benefits seen from the copper metallization in the FEOL layers, a sharp decrease in device yield has also been found.

Contact materials diffusing into the substrate typically damage the ultimate device. Barrier layers are usually sputtered onto the surfaces prior to deposition of these contact materials to prevent this diffusion. In the case of a tungsten contact material, the barrier layer is placed in order to prevent the fluorine, originating from the tungsten precursor, from attacking the surrounding substrate. These barrier layers have been successful in preventing the widespread diffusion of tungsten in current FEOL manufacturing techniques. However, these barriers, which are generally deposited using a physical vapor deposition (PVD) process, have not shown the same degree of success in the current experiments for copper metallization processes in the FEOL. Using current FEOL processing techniques, the yield of such copper metallization has only reached approximately 70%, compared with an approximate 98-100% yield for non-copper processing. This substantially diminished yield is generally insufficient to offer a practical alternative to the FEOL tungsten metallization despite the greatly decreased contact resistance because the cost to the manufacturer for implementing the process would likely be outweighed by the losses experienced from the limited yield.

### SUMMARY OF THE INVENTION

These and other problems are generally solved or circumvented, and technical advantages are generally achieved, by preferred embodiments of the present invention.

Representative embodiments of the present invention provide methods implemented in FEOL processing stages for forming a recess, which has a bottom and two sidewall surfaces, in a substrate. A barrier layer having about a 100% sidewall and bottom/floor coverage (i.e., step coverage) is deposited into the recess, after which copper is deposited into the recess over the barrier layer to form a contact.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a diagram illustrating a portion of a semiconductor device configured according to one embodiment of the present invention;

FIG. 2 is a diagram illustrating a cross-section of a device configured according to one embodiment of the present invention;

FIG. 3A is an scanning electron microscope (SEM) cross-section of a contact chain from a memory device configured according to the existing FEOL processing methods;

FIG. 3B is a SEM cross-section of a contact chain from a memory device configured according to one embodiment of the present invention; and

FIG. 4 is a flowchart illustrating example steps executed to implement one embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In examining the high failure rate of the copper metallization attempts in the FEOL processing, it is seen that the PVD process provides a step coverage of only less than 50% for the barrier layer. The margin for adjusting the barrier thickness on the bottom of high aspect ratio contact holes used in advanced technology nodes has already begun to reach the limitations with PVD techniques. For example, at a certain film thickness the characteristic deposition profile of PVD often prevents a further film growth at the bottom of the trench. Furthermore, by shrinking the contact size, the barrier thicknesses are inevitably reduced in order to maintain the portion of the barrier film at the optimum thickness ratio for the contact resistance.

Barrier materials usually have the highest resistivity within the contact layer stack and, therefore, their use should be optimized to the smallest acceptable thickness in order to achieve the lowest possible contact resistance. Otherwise, the benefits from implementing a contact material with superior conductivity would be compromised. Consequently, PVD techniques can no longer reliably provide the necessary barrier thickness and uniformity at the bottom of the contact that would allow the introduction of reliable high aspect ratio contacts in FEOL metallization. Thus, for the barriers deposited into high aspect contact holes by PVD processes with a maximum step coverage of less than 50%, copper still diffuses or leaches through the gaps that form at the bottom or the sidewalls of the contact. This diffusion then causes the surrounding substrate to be doped with copper, which would ultimately destroy the device, hence, the high failure rate.

In order to implement a contact in a semiconductor device, a contact hole with any desired shape and dimensions is etched in a substrate. Because copper is to be used for this contact, a barrier layer is deposited using a PVD process in existing FEOL processing methods. A barrier layer deposited in this manner has less than 50% step coverage of the bottom surface and the sidewall surfaces of the contact hole. A copper contact is thereafter deposited into the trench over the barrier layer.

Problems can exist with structures that have low step coverage. With further processing, if the barrier is not thick enough, copper can diffuse through gaps within the barrier layer to form a layer contaminated with copper. This contamination layer consumes the junction area of substrate 104. With this copper doping of substrate, the conductivity of contaminated layer increases, which in devices that include numerous components integrated into the same chip, can cause the semiconductor device to short out or fail to operate correctly or even completely.

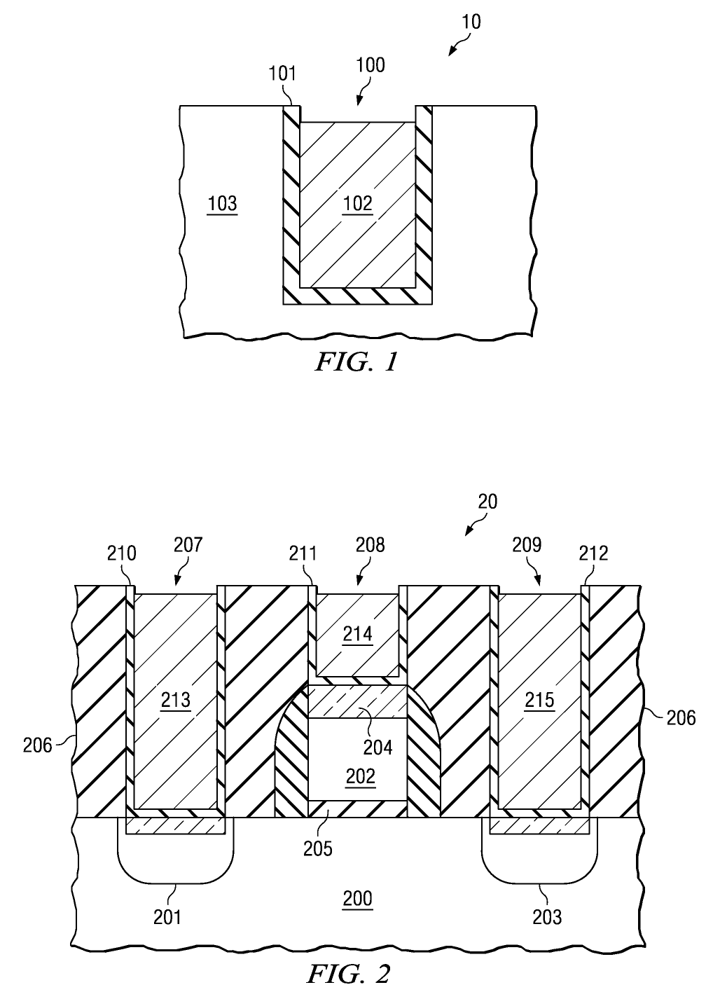

FIG. 1 is a diagram illustrating a portion of semiconductor device 10 configured according to one embodiment of the present invention. The process begins in a similar fashion to the existing FEOL methods. Circuit components, such as transistors, capacitors, diodes, are formed in a semiconductor layer. These components are then covered with a dielectric layer(s). The remaining structure can be referred to as substrate 103. In FIG. 1, substrate 103 is intentionally illustrated generically to emphasize that the specific components underlying contact 102 can greatly vary. FIG. 2 shows a more specific example where the substrate includes MOS transistors.

Continuing with FIG. 1, recess 100 is etched into substrate 103 where a contact or other conductor is desired. For example, recess 200 could be used for a copper plug that contacts to the semiconductor active area. However, instead of depositing barrier layer 101 using PVD, barrier layer 101 is deposited using atomic layer deposition (ALD). ALD has about a 100% step coverage compared with the maximum step coverage of 50% with PVD methods. Thus, the bottom thickness of barrier layer 101 could be deposited with the precise thickness which is necessary for avoiding gaps within its composition that would allow copper molecules or ions to diffuse through later on in the process flow.

Copper contact 102 is then deposited to provide the contact functionality in the FEOL. In a typical process, copper will be deposited within recess 100 and over the top surface of substrate 103. The copper overlying the substrate 103 can then be removed, for example, by a chemical-mechanical polishing (CMP) process.

Because the barrier thickness can be deposited precisely and reliable at the desired film thickness on the bottom of the contact hole there are virtually no weak spots in coverage of barrier layer 101, the copper does not diffuse into substrate 103, which keeps the failure rate low. This is true even after further processing that may include annealing or other high-temperature operations. Thus, the ALD process imparts distinctive structural characteristics to barrier layer 101 which allows for more reliable copper contacts in the FEOL processing stage.

By providing this ALD method to implement copper contacts within the FEOL stage, resulting devices will experience the enhanced performance measured in the previous tests. Moreover, because the failure rate is low, this alternative becomes a viable and profitable option to the existing FEOL processing methods.

It should be noted that barrier layer 101 may comprise any number of suitable materials that will structurally and chemically operate as barriers to copper. Examples of such barrier materials are tantalum, tantalum nitride, and the like. A single barrier or multiple barrier layers can be used.

ALD deposited barrier layers have been used in the back-end-of-line (BEOL) processing stages. However, the difference between the BEOL and FEOL stages causes a difference in the ALD barrier processing. In the BEOL stage, vias and contacts contact metal layers on both sides of the BEOL-stage device. Thus, a complete “seal” of the copper is unnecessary. As such, the process used in the BEOL stages is substantially different from the ALD process used in the FEOL stage.

Turning now to FIG. 2, device 20 is illustrated during the FEOL processing stage configured according to one embodiment of the present invention. Device 20 includes a typical MOS device comprising source region 201, gate structure 202, and drain region 203. Gate structure 202 comprises gate dielectric 205 and gate contact 204. Gate contact 204 is illustrated as a silicided material to provide a suitable contact. It should be noted that other actual conductive materials may be used to provide this contact region, such as polycrystalline silicon, tungsten, or the like. Source and drain regions 201 and 203 are also illustrated having a silicided contact area.

During FEOL processing, dielectric layer 206 is deposited onto the top surface of the MOS transistor. Contact holes 207-209 are formed or etched in dielectric 206 layer at the locations where further contacts are desired. Barrier liners 210-212 are then laid within contact holes 207-209 using a deposition process that achieves a near 100% step coverage rate, such as ALD. After depositing barrier liners 210-212, lined contact holes 207-209 are then filled with copper. From this process, copper contacts 213-215 are formed providing electrical coupling to source and drain regions 201 and 203 and gate structure 202 of the underlying MOS device. Moreover, because barrier liners 210-212 have nearly a 100% step coverage, no copper molecules or ions are allowed to diffuse into the underlying device layer. Thus, the eventual performance of device 20 will be greater than that of current FEOL processing which uses materials such as tungsten, aluminum, or the like, to provide contacts.

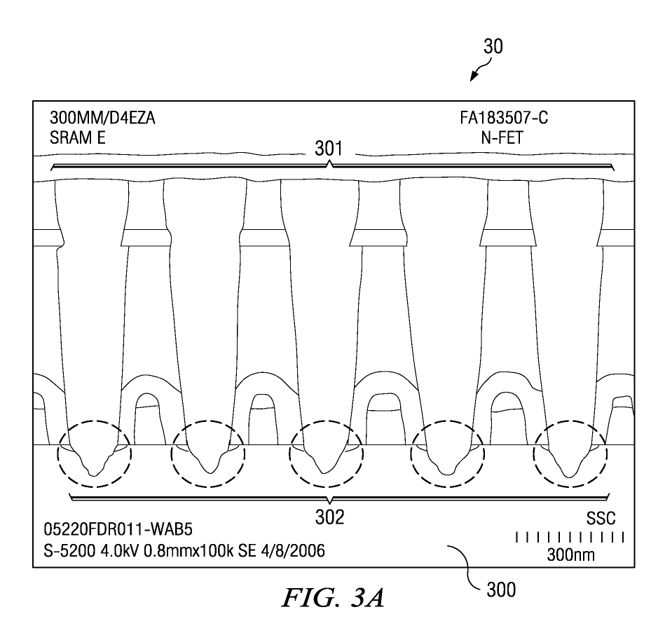

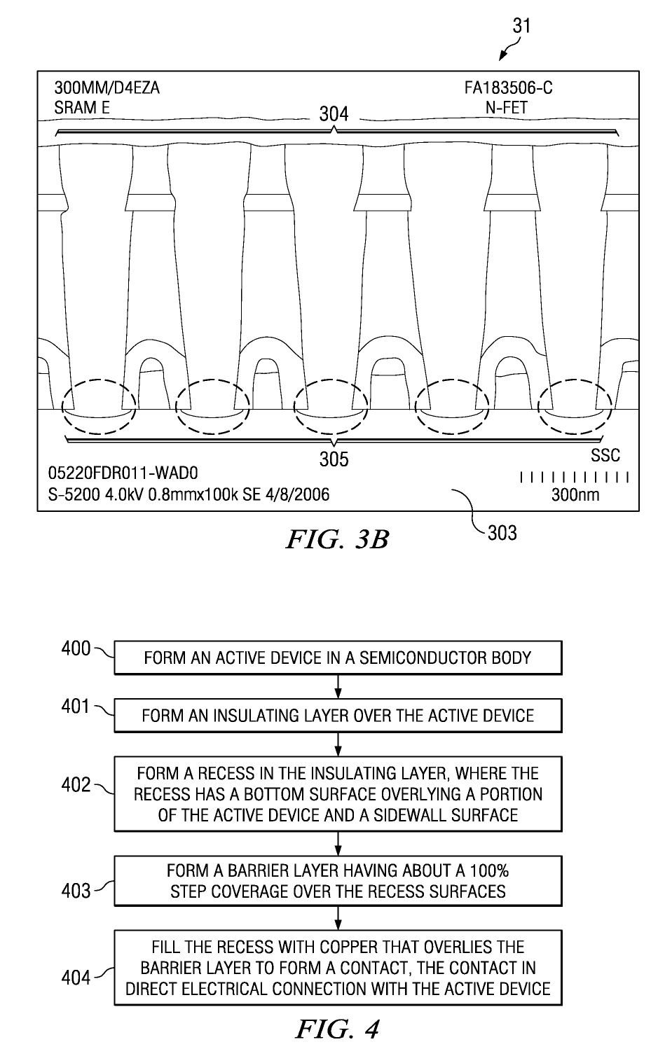

Turning now to FIG. 3A, a scanning electron microscope (SEM) cross-section of device 30 is illustrated in which a FEOL processing method using physical vapor deposited barrier layers. Contacts 301 formed in device 30 are comprised of copper and have been sealed with a barrier layer deposited using a PVD process. After further processing of device 30, diffused copper 302 can be seen at the bottom of each of contacts 301. This contamination of the surrounding substrate creates an unpredictable functionality of device 30. This diffused copper 302 may cause device 30 to be damaged or even destroyed.

FIG. 3B, in contrast, is a diagram illustrating a SEM cross-section of device 31 configured according to one embodiment of the present invention. Contacts 304 have been formed of copper within device 31 using an ALD process to form the barrier layers. As can be seen in FIG. 3B, after further processing, connection zones 305 do not experience any copper diffusion through the ALD-processed barrier layer because the ALD process with about a 100% step coverage provides the necessary thickness and uniformity in the deposition of the barrier layer. As a consequence the detrimental effects of copper penetration can be avoided. Device 31, therefore, will operate more predictably and more reliably, at least with respect to having no diffused copper 302 (FIG. 3A).

FIG. 4 is a flowchart illustrating example steps executed to implement one embodiment of the present invention. In step 400, an active device is formed in a semiconductor body. An insulating layer is them formed, in step 401, over the active device. In step 402, a recess is formed in the insulating layer, where the recess has a bottom surface overlying a portion of the active device and a sidewall surface. A barrier layer is formed, in step 403, having about a 100% step coverage over the recess surfaces. In step 404, the recess is filled with copper that overlies the barrier layer to form a contact, the contact in direct electrical connection with the active device.

It should be noted that while the ALD process has been described herein, any deposition process that results in about a 100% step coverage may be used with the various embodiments of the present invention.

Various embodiments of the present invention provide advantages. For example, one advantage of a preferred embodiment of the present invention is that copper can be used in the FEOL process for contacts without serious impact in yield and, thus, without serious increase in manufacturing revenue.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of making a semiconductor device, said method comprising:
forming an active device is a semiconductor body;
forming an insulating layer over the active device;
forming a recess in the insulating layer, said recess having a bottom surface and sidewall surfaces, the bottom surface overlying a portion of the active device;
forming a barrier layer having about a 100% step coverage over the sidewall surfaces and said bottom surface; and
filling said recess with copper that overlies said barrier layer to form a contact, the contact in direct electrical connection with the active device.

2. The method of claim 1, wherein forming said barrier layer comprises depositing said barrier layer using an atomic layer deposition (ALD).

3. The method of claim 1, wherein said barrier layer comprises tantalum.

4. The method of claim 3, wherein said barrier layer comprises tantalum nitride.

5. The method of claim 1, wherein the recess exposes a surface of the active device.

6. The method of claim 5, wherein the recess exposes a semiconductor surface.

7. The method of claim 6, wherein the barrier layer is formed in direct contact with the semiconductor surface.

8. The method of claim 5, wherein the recess exposes a silicide surface.

9. The method of claim 8, wherein the barrier layer is formed in direct contact with the silicide surface.

10. A method of making a semiconductor device, said method comprising:
forming an active device is a semiconductor body;
forming an insulating layer over the active device;
forming a recess in the insulating layer, said recess having a bottom surface and sidewall surfaces, the bottom surface overlying a portion of the active device;
forming a barrier layer over the sidewall surfaces and said bottom surface, the barrier being formed using an atomic layer deposition (ALD) process; and
filling said recess with copper that overlies said barrier layer to form a contact, the contact in direct electrical connection with the active device.

11. The method of claim 10, wherein said barrier layer comprises tantalum.

12. The method of claim 11, wherein said barrier layer comprises tantalum nitride.

13. The method of claim 10, wherein the recess exposes a surface of the active device.

14. The method of claim 13, wherein the recess exposes a semiconductor surface.

15. The method of claim 14, wherein the barrier layer is formed in direct contact with the semiconductor surface.

16. The method of claim 13, wherein the recess exposes a silicide surface.

17. The method of claim 16, wherein the barrier layer is formed in direct contact with the silicide surface.

18. The method of claim 10, wherein filling said recess with copper comprises completely filling said recess.

19. A semiconductor device comprising:
a semiconductor component disposed at a surface of a semiconductor body;
an insulating layer overlying the semiconductor body;
a copper contact directly electrically connected to said semiconductor component, wherein the copper contact extending through the insulating layer; and
a barrier layer located between the copper contact and said insulating layer, wherein said barrier layer is formed to create about a 100% step coverage to shield said insulating layer and the semiconductor body from copper diffusing from said copper contact.

20. The semiconductor device of claim 19, wherein barrier layer comprises a barrier layer formed by an atomic layer deposition (ALD) process.

21. The semiconductor device of claim 19, wherein said barrier layer comprises tantalum.

22. The semiconductor device of claim 19, wherein said barrier layer comprises tantalum nitride.
